(19) United States
(12) Patent Application Publication
(10) Pub. No.: US 2026/0271697 A1
(43) Pub. Date: Sep. 10, 2026

(54) SEMICONDUCTOR DEVICE, FABRICATION METHOD THEREOF, AND MEMORY SYSTEM

(71) Applicant: Yangtze Memory Technologies Co., Ltd., Wuhan (CN)

(72) Inventors: Fazhan Wang, Wuhan (CN); Yali Guo, Wuhan (CN); Bin Yuan, Wuhan (CN); Baoqing Sun, Wuhan (CN); Danyang Wei, Wuhan (CN); Wei Xu, Wuhan (CN); Zongliang Huo, Wuhan (CN)

(21) Appl. No.: 19/435,514

(22) Filed: Dec. 29, 2025

(30) Foreign Application Priority Data
Mar. 6, 2025 (CN) 202510265708.8

(51) Int. Cl. H10W 20/20; H10B 12/00; H10D 80/30; H10W 20/41

(52) U.S. Cl. CPC H10W 20/213; H10B 12/05; H10B 12/315; H10D 80/30; H10W 20/435

(57) ABSTRACT

Examples of the present disclosure provide a semiconductor device, a fabrication method thereof, and a memory system. The semiconductor device includes: a memory array in a first region of the semiconductor device; first semiconductor portions located in a second region of the semiconductor device and spaced apart from each other along a first direction; a conductive structure; and an isolation structure. The second region is different from the first region; the conductive structure is on a first side of the first semiconductor portions; and the isolation structure includes a first isolation portion in the second region, where the first isolation portion extends along the first direction or a second direction, the first isolation portion extends through at least one first semiconductor portion, and the second direction intersects with the first direction.

### CROSS-REFERENCE TO RELATED APPLICATIONS

This application claims the benefit of priority to Chinese Application No. 202510265708.8, filed on March 6, 2025, which is hereby incorporated by reference in its entirety.

### TECHNICAL FIELD

Examples of the present disclosure relate to the field of semiconductor technology, and relate to, but are not limited to, a semiconductor device, a fabrication method thereof, and a memory system.

### BACKGROUND

The semiconductor device is divided into a volatile memory and a non-volatile memory according to whether stored data is retained when power is turned off, and the volatile memory in which data will be lost when power is turned off may include a Static Random Access Memory (SRAM) and a Dynamic Random Access Memory (DRAM).

With the continuous development of the semiconductor technology, the arrangement density of conductive elements in the semiconductor device is increasing accordingly, which leads to the continuous reduction of distance between the conductive elements, and then directly leads to the increased parasitic capacitance between the conductive elements, which will affect the performance of the semiconductor device.

### SUMMARY

According to one aspect of the present disclosure a semiconductor device is provided. The semiconductor device may include a memory array, a plurality of first semiconductor portions, a conductive structure, and an isolation structure. The memory array may be in a first region of the semiconductor device. The plurality of first semiconductor portions may be in a second region of the semiconductor device, and the plurality of first semiconductor portions may be spaced apart from each other along a first direction. the second region may be different from the first region. The conductive structure may be located on a first side of the plurality of first semiconductor portions; and the isolation structure comprises a first isolation portion in the second region. The first isolation portion extends along the first direction or a second direction, the first isolation portion extends through at least one of the first semiconductor portions, and the second direction intersects with the first direction.

In some examples, the isolation structure may further include a second isolation portion between adjacent first semiconductor portions along the first direction. A height of the second isolation portion may be substantially the same as a height of the first isolation portion.

In some examples, the memory array may include a plurality of second semiconductor portions located in the first region and arranged in an array along the first direction and the second direction;

In some examples, the isolation structure may further include a third isolation portion between adjacent second semiconductor portions along the first direction, and a height of the third isolation portion may be substantially the same as a height of the first isolation portion.

In some examples, a size in the first direction of the first isolation portion close to the conductive structure may be greater than or equal to a size in the first direction of the first isolation portion away from the conductive structure.

In some examples, a height of the second semiconductor portion may be substantially the same as a height of the first semiconductor portion.

In some examples, a material of the second semiconductor portion may be the same as a material of the first semiconductor portion.

In some examples, a size in the first direction of the first isolation portion close to the conductive structure may be less than or equal to a size in the first direction of the first isolation portion away from the conductive structure.

In some examples, the first isolation portion may include a first isolation sub-portion and a second isolation sub-portion, the second isolation sub-portion may be located between the conductive structure and the first isolation sub-portion; a size in the first direction of the first isolation sub-portion close to the conductive structure may be greater than or equal to a size in the first direction of the first isolation sub-portion away from the conductive structure; and a size in the first direction of the second isolation sub-portion close to the conductive structure may be less than or equal to a size in the first direction of the second isolation sub-portion away from the conductive structure.

In some examples, the first isolation portion extends through the plurality of first semiconductor portions.

In some examples, the isolation structure may include a plurality of first isolation portions arranged along the first direction or the second direction.

In some examples, the plurality of first isolation portions are arranged symmetrically on two opposite sides of the conductive structure along the second direction.

In some examples, an orthographic projection of the conductive structure and orthographic projections of the plurality of first isolation portions at least partially overlap.

In some examples, the conductive structure may include a data pad.

In some examples, the memory array may further include a transistor and a capacitor, the transistor may include a second semiconductor portion, the capacitor may be on a side of the second semiconductor portion close to the conductive structure, and the capacitor may be connected to an end of the second semiconductor portion close to the conductive structure.

In some examples, the semiconductor device may further include a connection structure in the second region, where the connection structure extends along a third direction, the connection structure extends through the isolation structure, and the third direction may be perpendicular to both the second direction and the first direction.

In some examples, the semiconductor device may include a first semiconductor structure and a second semiconductor structure that are bonded together, where the memory array, the conductive structure, the isolation structure and the plurality of first semiconductor portions are located in the first semiconductor structure, and the connection structure extends through a portion of the first semiconductor structure along the third direction.

In some examples, the semiconductor device may further include an interconnection structure on a second side of the plurality of first semiconductor portions, where the second side and the first side are opposite along the third direction, and the connection structure may be connected to each of the conductive structure and the interconnection structure.

In some examples, the semiconductor device may include a dynamic random access memory.

According to another aspect of the present disclosure a fabrication method of a semiconductor device is provided. The fabrication method of a semiconductor device may include forming a memory array in a first region of the semiconductor device; forming a plurality of first semiconductor portions spaced apart from each other along a first direction in a second region of the semiconductor device. The second region may be different from the first region. The fabrication method of a semiconductor device may further include forming a conductive structure on a first side of the plurality of first semiconductor portions; and forming an isolation structure comprising a first isolation portion in the second region. The first isolation portion extends along the first direction or a second direction, the first isolation portion extends through at least one of the first semiconductor portions, and the second direction intersects with the first direction.

In some examples, forming the isolation structure may include: forming a second isolation portion between adjacent first semiconductor portions along the first direction. A height of the second isolation portion may be substantially the same as a height of the first isolation portion.

In some examples, forming a memory array in a first region of the semiconductor device may include: forming a plurality of second semiconductor portions arranged in an array along the first direction and the second direction in the first region; and forming an isolation structure may include: forming a third isolation portion between adjacent second semiconductor portions along the first direction, and a height of the third isolation portion may be substantially the same as a height of the first isolation portion.

In some examples, forming an isolation structure may include providing a substrate; etching the substrate to form a plurality of first trenches spaced apart from each other along the first direction, where the first trenches in the second region separate the substrate into the plurality of first semiconductor portions, and the first trenches in the first region separate the substrate into a plurality of initial second semiconductor portions; forming an initial isolation portion in the plurality of first trenches, where the initial isolation portion in the second region constitutes the second isolation portion; and forming the plurality of second semiconductor portions arranged in an array along the first direction and the second direction in the first region may include: etching the plurality of initial second semiconductor portions and the initial isolation portion in the first region to form a plurality of second trenches spaced apart from each other along the second direction, where the plurality of second trenches separate the initial second semiconductor portions into the plurality of second semiconductor portions, and the initial isolation portion on both sides of the second trenches constitutes the third isolation portion.

In some examples, forming the isolation structure may further include: etching at least one of the first semiconductor portions to form a third trench extending along the first direction or the second direction, the third trench extending through the at least one of the first semiconductor portions; and forming the first isolation portion in the third trench.

In some examples, the third trench and the plurality of first trenches are formed simultaneously by etching, and the first isolation portion and the initial isolation portion are formed simultaneously.

In some examples, the plurality of first trenches are formed on a front surface of the substrate, and the third trench may be formed on a back surface of the substrate after being thinned, and where a distance between the front surface of the substrate and the conductive structure may be less than a distance between the back surface of the substrate and the conductive structure.

In some examples, the third trench extends through the plurality of first semiconductor portions.

In some examples, forming the isolation structure may further include: etching at least one of the first semiconductor portions to form a first sub-trench, where a bottom of the first sub-trench extends into an etched one of the first semiconductor portions; forming a first isolation sub-portion in the first sub-trench, where a size in the first direction of the first isolation sub-portion close to the conductive structure may be greater than or equal to a size in the first direction of the first isolation sub-portion away from the conductive structure; after thinning the substrate, etching a remainder of the first semiconductor portions to form a second sub-trench, where the second sub-trench exposes the first isolation sub-portion; and forming a second isolation sub-portion in the second sub-trench, where a size in the first direction of the second isolation sub-portion close to the conductive structure may be less than or equal to a size in the first direction of the second isolation sub-portion away from the conductive structure.

In some examples, the fabrication method may further include: forming a connection structure in the second region, where the connection structure extends along a third direction, the connection structure extends through the isolation structure, and the third direction may be perpendicular to both the second direction and the first direction.

In some examples, the fabrication method may further include: bonding a first semiconductor structure with a second semiconductor structure, the first semiconductor structure comprising the memory array, the conductive structure, the isolation structure and the plurality of first semiconductor portions, where the connection structure extends through a portion of the first semiconductor structure along the third direction.

In some examples, the fabrication method may further include: forming an interconnection structure on a second side of the plurality of first semiconductor portions, where the second side and the first side are opposite along the third direction, and the connection structure may be connected to each of the conductive structure and the interconnection structure.

In some examples, the conductive structure may include a data pad.

According to another aspect of the present disclosure a memory system is provided. The memory system may include at least one semiconductor device according to any example in the first aspect of the example of the present disclosure; and a controller coupled to the semiconductor device.

In some examples, the memory system may include a high bandwidth memory.

In some examples, the first isolation portion may be arranged in the second region of the semiconductor device, and the first isolation portion extends through at least one first semiconductor portion. As such, the first isolation portion extending through the first semiconductor portion may separate apart the first semiconductor portion, thereby reducing the parasitic capacitance between the first semiconductor portion and the conductive structure, and facilitating improvement on data input or output speed of the semiconductor device.

### BRIEF DESCRIPTION OF THE DRAWINGS

In the drawings, like reference numerals refer to the same or similar parts or elements throughout the various figures unless otherwise specified. The figures are not necessarily drawn to scale. It should be understood that these drawings depict only some implementations disclosed according to the present application and are not to be considered as limitations on the scope of the present application.

FIG. 1 is a schematic diagram illustrating a system according to an example of the present disclosure.

FIG. 2A and FIG. 2B are schematic diagrams of a memory device according to an example of the present disclosure.

FIG. 3 is a top view of a semiconductor device according to an example of the present disclosure.

FIG. 4A is a schematic cross-sectional view of another semiconductor device according to an example of the present disclosure.

FIG. 4B is a top view of another semiconductor device according to an example of the present disclosure.

FIGS. 5A to 5D are top views of a first isolation portion according to an example of the present disclosure.

FIG. 6A is a schematic cross-sectional view of a semiconductor device along a first direction according to an example of the present disclosure.

FIG. 6B is a schematic cross-sectional view of a semiconductor device along a second direction according to an example of the present disclosure.

FIG. 7 is a flow diagram of a fabrication method of a semiconductor device according to an example of the present disclosure.

FIG. 8 to FIG. 11 are partial schematic diagrams illustrating a fabrication process of a semiconductor device according to an example of the present disclosure.

FIG. 12 is a schematic diagram of a memory system according to an example of the present disclosure.

FIG. 13 is a schematic diagram illustrating another system according to an example of the present disclosure.

FIG. 14 is a schematic diagram illustrating yet another system according to an example of the present disclosure.

### DETAILED DESCRIPTION

In order to facilitate understanding of the present disclosure, examples of the present disclosure will be described in more detail below with reference to the related drawings. Although the example implementations of the present disclosure are shown in the drawings, it should be understood that the present disclosure may be implemented in various forms and should not be limited by the specific examples set forth herein. On the contrary, these examples are provided to provide a more thorough understanding of the present disclosure and to fully convey the scope of the present disclosure to those skilled in the art.

In the following description, numerous specific details are set forth in order to provide a more thorough understanding of the present disclosure. However, it will be apparent to those skilled in the art that the present disclosure may be practiced without one or more of these details. In some examples, in order to avoid confusion with the present disclosure, some technical features known in the art are not described; that is, all features of an actual example may not be described herein, and well-known functions and structures are not described in detail.

In general, terminologies may be understood at least in part from usage in context. For example, the term “one or more” as used herein, depending at least in part upon the context, may be used to describe any feature, structure, or characteristic in a singular sense or may be used to describe combinations of features, structures or characteristics in a plural sense. Similarly, depending at least in part upon the context, terms such as “a,” “an,” or “the,” may be understood to convey a singular usage or to convey a plural usage. In addition, depending at least in part on context, a phrase “based on” may be understood as not necessarily intended to convey an exclusive set of factors and may instead allow for existence of additional factors not necessarily expressly described.

Unless otherwise defined, the terminologies used herein is for the purpose of describing particular examples only and is not intended to limit the disclosure. As used herein, the singular forms “a”, “an” and “the” are intended to include the plural forms as well, unless the context clearly indicates otherwise. It will be further understood that the terms “consist of” and/or “comprise”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” comprises any and all combinations of the associated listed items.

In order to thoroughly understand the present disclosure, detailed steps and detailed structures are provided in the following description to explain the technical solutions of the present disclosure. Some examples of the present disclosure are described in detail below, but the present disclosure may have other implementations in addition to these detailed descriptions.

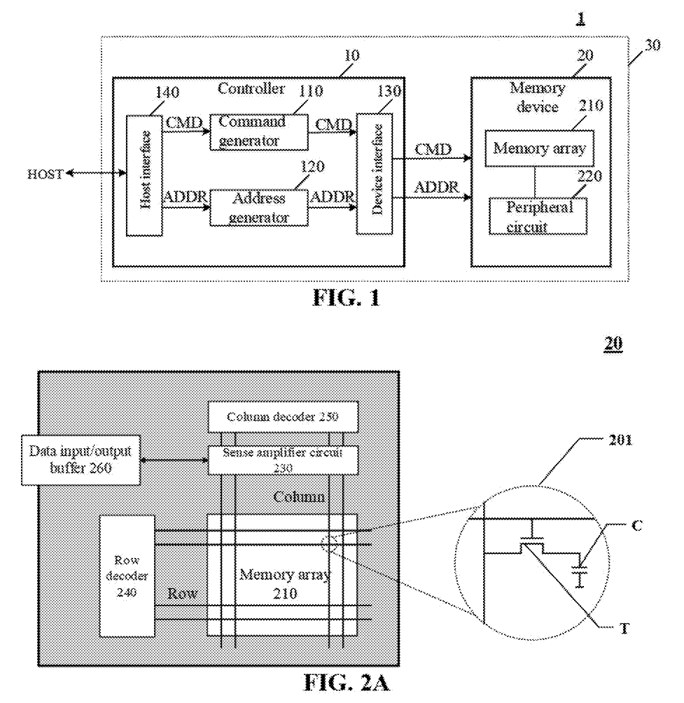

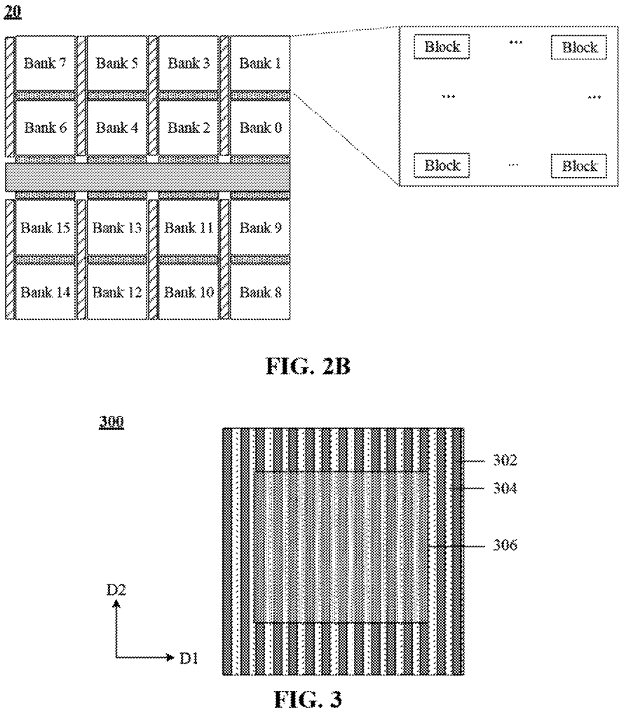

FIG. 1 is a schematic diagram of a system according to an example of the present disclosure, and FIGS. 2A and 2B are schematic diagrams of a memory device according to an example of the present disclosure.

Referring to FIG. 1, a system 1 may comprise a HOST and a memory system 30. In the examples of the present disclosure, the system 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device therein.

The HOST may be a processor (e.g., a central processing unit (CPU)) or a system on chip (SoC) (e.g., an application processor (AP)) of the electronic device. The memory system 30 has one or more memory devices 20 and a controller 10. The HOST may be configured to send data to or receive data from the memory device 20. The controller 10 is coupled to the memory device 20 and the HOST and is configured to control the memory device 20. The controller 10 may manage data stored in the memory device 20 and communicate with the HOST.

The controller 10 may be configured to control operations of the memory device 20, such as read, write, and refresh operations. In some examples, the controller 10 is further configured to process an error correction code (ECC) on data read from or written to the memory device 20. The controller 10 may also perform any other suitable functions, such as formatting the memory device 20.

In some examples, the controller 10 and the one or more memory devices 20 may be integrated into various types of memory devices. For example, the controller 10 may be integrated into a north bridge of a computer motherboard or directly into a computer CPU, and multiple memory devices 20 may be integrated into a memory module. That is, the memory system 30 may be implemented and packaged into different types of end electronic products.

The controller 10 may send data to or receive data from the HOST and may send a command CMD and an address ADDR to the memory device 20. The controller 10 may comprise a command generator 110, an address generator 120, a device interface 130, and a host interface 140. The host interface 140 may receive the command CMD and the address ADDR from the HOST. The command generator 110 may generate an access command, a refresh command, or the like by decoding the command CMD received from the HOST and may provide the access command and the refresh command to the memory device 20 through the device interface 130. The access command may be a signal instructing the memory device 20 to write or read data by accessing a row of the memory array 210 corresponding to the address ADDR. The refresh command may instruct the memory array 210 of the memory device 20 to perform a refresh operation for storing data.

The address generator 120 in the controller 10 may generate a row address and a column address to be accessed in the memory array 210 by decoding the address ADDR received from the host interface 140. In addition, the memory device 20 may generate addresses of memory banks to be accessed when the memory array 210 comprises a plurality of memory banks.

Further, the controller 10 may control memory device operations such as writing and reading by providing various signals to the memory device 20 via the device interface 130. For example, the controller 10 may provide a write command to the memory device 20. The write command is used to instruct the memory device 20 to perform a write operation to store data into the memory device 20. Memory device 20 may be random access memory (RAM) such as dynamic random access memory (DRAM), synchronous DRAM (SDRAM), double data rate SDRAM (DDR SDRAM), DDR2 SDRAM, DDR3 SDRAM, phase change RAM (PRAM), magnetic RAM (MRAM), resistive RAM (RRAM), etc.

Referring to FIGS. 1, 2A and 2B, the memory device 20 comprises a memory array 210 and a peripheral circuit 220. The memory array 210 comprises a plurality of memory banks, and FIG. 2B shows 16 memory banks, namely Bank0 to Bank15, as an example. Each memory bank comprises a plurality of memory blocks, each memory block comprises a plurality of rows of memory cells and a plurality of columns of memory cells, each row of memory cells is coupled to a corresponding word line, and each column of memory cells is coupled to a corresponding bit line.

It should be noted that the 16 memory banks and the arrangement thereof shown in FIG. 2B are only examples, and the number and arrangement of the memory banks in the memory device may be adjusted according to actual conditions and process requirements. For example, the 4 rows of memory banks in FIG. 2B may be reduced to 2 rows each having 4 memory banks, i.e., a total of 8 memory banks. The examples of the present disclosure has no specific limitations on the number and arrangement of the memory banks.

The peripheral circuit 220 may comprise: a control circuit corresponding to each memory block, such as a sensing amplifier (SA) circuit 230 and a word line driver (Word-Line Driver WLD); a control circuit corresponding to each memory bank, such as a row decoder 240 and a column decoder 250; and a control circuit corresponding to all memory banks, such as a data input/output buffer 260, a command buffer, a command decoder, an address buffer, and a mode register.

The peripheral circuit 220 may write data to the memory array 210 or read data from the memory array 210 based on a command CMD and an address ADDR received from the controller 10 or may provide control signals CTRL for refreshing memory cells included in the memory array 210 to the row decoder 240 and the column decoder 250. In other words, the peripheral circuit 220 may perform all operations to process data in the memory array 210.

Referring to FIG. 2A, the memory device comprises at least one DRAM Die, and each DRAM die comprises a memory array 210. The memory array 210 comprises a plurality of memory cells 201 arranged in an array, and each memory cell 201 comprises a transistor T and a capacitor C. The main operation principle of the memory cell is to utilize the amount of charge stored in the capacitor to represent whether a binary bit is 1 or 0. The memory cells are arranged in an array, which can be regarded as a typical network structure, and the memory array utilizes rows and columns to specify addresses. By specifying an intersection of a row and a column (by specifying the row address and the column address of the DRAM), the controller can independently access each memory cell in the DRAM chip and perform read, write, or refresh operations on the data stored therein.

FIG. 3 is a top view of a semiconductor device according to an example of the present disclosure, and the semiconductor device shown in FIG. 3 may be an example of the memory device 20 in FIGS. 1, 2A and 2B. Referring to FIG. 3, the semiconductor device 300 comprises a plurality of semiconductor portions 302, an isolation portion 304, and a conductive structure 306. The plurality of semiconductor portions 302 are spaced apart from each other along the first direction D1. Each semiconductor portion 302 extends along the second direction D2. Adjacent semiconductor portions 302 are physically isolated by the isolation portion 304, and the conductive structure 306 is located on one side of the plurality of semiconductor portions 302. For ease of description, other film layers between the conductive structure 306 and the plurality of semiconductor portions 302 are omitted in the top view of FIG. 3.

The memory array and the plurality of semiconductor portions 302 in FIG. 2A may be located in different regions of the semiconductor device respectively. For example, the memory array may be located in a first region of the semiconductor device, the plurality of semiconductor portions 302 may be located in a second region of the semiconductor device, and the conductive structure 306 may also be located in the second region. As an example, a plurality of semiconductor portions may be formed in both the first region and the second region by etching the substrate. The semiconductor portion located in the first region constitutes a transistor of the DRAM memory cell. The semiconductor portion 302 located in the second region may serve as a dummy structure, and the dummy structure generally has functions of supporting and balancing stress. The conductive structure may comprise a data pad (DQ pad) for inputting or outputting data, for example, inputting data to be written into the memory array or outputting data read from the memory array.

With the continuous development of semiconductor technology, the distance between the semiconductor portion 302 and the conductive structure 306 in the second region is reduced, and the parasitic capacitance between the semiconductor portion 302 and the conductive structure 306 is increased, resulting in the performance of the semiconductor device being affected, for example, the speed of data input or output is reduced.

Based on one or more of the above technical problems, an example of the present disclosure provides another semiconductor device. The semiconductor device comprises a memory array, a plurality of first semiconductor portions, a conductive structure, and an isolation structure; the memory array is located in a first region of the semiconductor device; the plurality of first semiconductor portions are located in a second region of the semiconductor device, and the plurality of first semiconductor portions are spaced apart from each other along a first direction, where the second region is different from the first region; the conductive structure is located on a first side of the plurality of first semiconductor portions; and the isolation structure comprises a first isolation portion located in the second region, where the first isolation portion extends along the first direction or a second direction, the first isolation portion extends through at least one first semiconductor portion, and the second direction intersects with the first direction. As such, the first isolation portion extending through the first semiconductor portion may separate apart the first semiconductor portion, thereby reducing the parasitic capacitance between the first semiconductor portion and the conductive structure, and facilitating the improvement of data input or output speed of the semiconductor device.

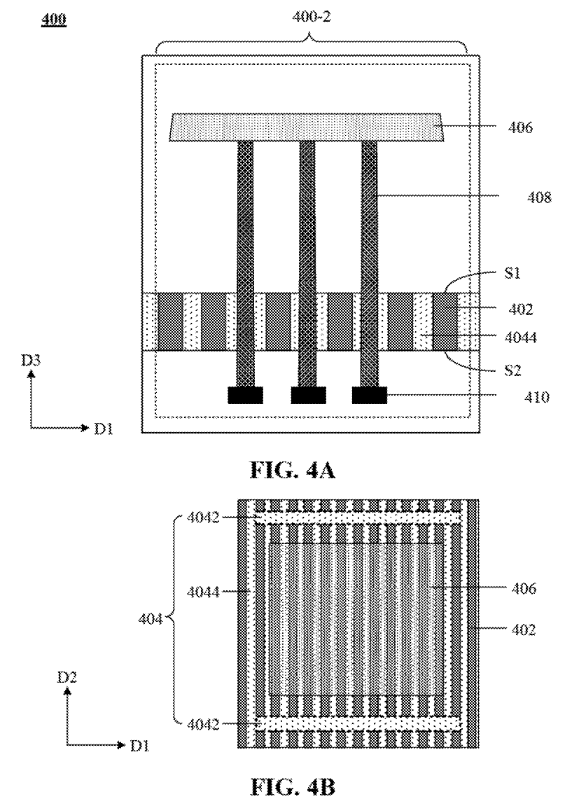

FIG. 4A is a schematic cross-sectional view of another semiconductor device according to an example of the present disclosure, FIG. 4B is a top view of another semiconductor device according to an example of the present disclosure, and the semiconductor device shown in FIGS. 4A and 4B may be an example of the memory device 20 in FIGS. 1, 2A and 2B. Another semiconductor device provided by an example of the present disclosure will be illustrated below with reference to FIGS. 4A and 4B.

The semiconductor device 400 may comprise a memory array in a first region of the semiconductor device 400. Regarding to the memory array, reference may be made to related description of the memory array 210 in FIG. 1, FIG. 2A, and FIG. 2B. In the examples of the present disclosure, the semiconductor device 400 includes, but is not limited to, a DRAM.

Referring to FIG. 4A and FIG. 4B, the semiconductor device 400 may further comprise a plurality of first semiconductor portions 402. The plurality of first semiconductor portions 402 are located in the second region 400-2 of the semiconductor device 400, and the second region 400-2 is different from the first region. In the examples of the present disclosure, the memory array and the plurality of first semiconductor portions 402 may be located in different regions of the semiconductor device 400 respectively, i.e., the first region and the second region 400-2. For ease of description, only the second region 400-2 is shown in FIG. 4A and FIG. 4B.

Referring to FIG. 4A, the plurality of first semiconductor portions 402 are spaced apart from each other along the first direction D1. In the examples of the present disclosure, the plurality of first semiconductor portions 402 shown in FIG. 4A may be formed by etching the substrate in the second region 400-2. The material of the first semiconductor portion 402 comprises a semiconductor material, for example, an elementary semiconductor material (for example, silicon (Si) or germanium (Ge)), a III-V compound semiconductor material (for example, gallium nitride (GaN), gallium arsenide (GaAs) or indium phosphide (InP)), a II-VI compound semiconductor material (for example, zinc sulfide (ZnS), cadmium sulfide (CdS) or cadmium telluride (CdTe)), an organic semiconductor material or other semiconductor materials known in the art.

Referring to FIG. 4A, the semiconductor device 400 may further comprise a conductive structure 406. The conductive structure 406 is located on the first side S1 of the plurality of first semiconductor portions 402 and may also be located in the second region 400-2. In some examples, the conductive structure 406 is electrically coupled to the memory array. The conductive structure 406 may input data to be written to the memory array, or the conductive structure 406 may output data read from the memory array.

As an example, the conductive structure 406 comprises a data pad, and the conductive structure 406 may also be other structures with conductive properties, such as an interconnection structure or a bit line electrically coupled to the memory array. A material of the conductive structure 406 comprises a conductive material, for example, at least one of tungsten, copper, and aluminum.

Referring to FIG. 4B, the semiconductor device 400 may further comprise an isolation structure 404. The isolation structure 404 may physically isolate the semiconductor portions from each other. A material of the isolation structure 404 comprises at least one of silicon oxide, silicon nitride, and silicon oxynitride. The isolation structure 404 comprises a first isolation portion 4042 located in the second region 400-2, wherein the first isolation portion 4042 extends along the first direction D1, and the first isolation portion 4042 extends through at least one first semiconductor portion 402. In the examples of the present disclosure, the extension direction is used to describe the layout direction of a certain component in space to distinguish the layout of different components, and the extension direction is usually related to the design of the semiconductor device.

As an example, the first isolation portion 4042 shown in FIG. 4B extends along the first direction D1. The first isolation portion 4042 extends through the plurality of first semiconductor portions 402. One first isolation portion 4042 extending along the first direction D1 may separate each first semiconductor portion 402 into two semiconductor sub-portions spaced apart from each other along the second direction D2. The first isolation portion 4042 is located between the two semiconductor sub-portions arranged along the second direction D2. As such, the first isolation portion 4042 may separate apart the plurality of first semiconductor portions 402 extending in the second direction D2, thereby reducing the parasitic capacitance between the first semiconductor portion 402 and the conductive structure 406, and improving the speed of inputting or outputting data by the semiconductor device 400.

In other examples, the first isolation portion 4042 may extend through one first semiconductor portion 402, i.e., the first isolation portion 4042 separates apart one first semiconductor portion 402 extending along the second direction D2. The number of the first semiconductor portions 402 through which the first isolation portion 4042 extends is not specifically limited in the examples of the present disclosure.

It should be noted that, in the examples of the present disclosure, the first direction (denoted as D1 direction in the drawings) and second direction (denoted as D2 direction in the drawings) that intersect with each other may be defined in a plane parallel to the substrate, and the direction perpendicular to the plane of the substrate is defined as the third direction (denoted as D3 direction in the drawings). The D1 direction intersects with the D2 direction, and an included angle between the D1 direction and the D2 direction includes an acute angle, a right angle, or an obtuse angle. For ease of description, the following description is illustrated based on an example in which an included angle between the D1 direction and the D2 direction is a right angle, i.e., the D1 direction, the D2 direction, and the D3 direction are perpendicular to each other.

In some examples, referring to FIG. 4A and FIG. 4B, the isolation structure 404 further comprises a second isolation portion 4044. The second isolation portion 4044 is located between adjacent first semiconductor portions 402 along the first direction D1, wherein a height of the second isolation portion 4044 is substantially the same as a height of the first isolation portion 4042. The second isolation portion 4044 may extend along the second direction D2 to physically isolate the plurality of first semiconductor portions 402 spaced apart from each other along the first direction D1 from each other. A material of the second isolation portion 4044 comprises at least one of silicon oxide, silicon nitride, and silicon oxynitride.

As an example, FIG. 4B shows that the second isolation portion 4044 extending in the second direction D2 is in contact with the first isolation portion 4042 extending along the first direction D1. The materials of the second isolation portion 4044 and the first isolation portion 4042 may be the same, for example, the materials of the second isolation portion 4044 and the first isolation portion 4042 are both silicon oxide, and thus there is no obvious interface at the position of contact between the second isolation portion 4044 and the first isolation portion 4042. As such, the second isolation portion 4044 and the first isolation portion 4042 may be formed by filling simultaneously, to simplify the fabrication process. In other examples, the materials of the second isolation portion 4044 and the first isolation portion 4042 may be different.

As an example, the surface of the second isolation portion 4044 close to the conductive structure 406 and the surface of the first isolation portion 4042 close to the conductive structure 406 are at substantially the same height, i.e., the surface of the second isolation portion 4044 close to the conductive structure 406 and the surface of the first isolation portion 4042 close to the conductive structure 406 are substantially coplanar. A surface of the second isolation portion 4044 away from the conductive structure 406 and a surface of the first isolation portion 4042 away from the conductive structure 406 are at substantially the same height, i.e., a surface of the second isolation portion 4044 away from the conductive structure 406 and a surface of the first isolation portion 4042 away from the conductive structure 406 are substantially coplanar.

It should be noted that the “height” used in the present disclosure denotes a dimension of a certain structure or a certain film layer in the D3 direction, which will not be repeated below for brevity. Substantially the same height may indicate that the height of the second isolation portion 4044 and the height of the first isolation portion 4042 are completely the same; or the difference between the height of the second isolation portion 4044 and the height of the first isolation portion 4042 is very small and negligible.

In an example of the present disclosure, the isolation structure 404 further comprises a second isolation portion 4044, and the second isolation portion 4044 may physically isolate the plurality of first semiconductor portions 402 spaced apart from each other along the first direction D1 from each other. In addition, the height of the second isolation portion 4044 is substantially the same as the height of the first isolation portion 4042, and the second isolation portion 4044 and the first isolation portion 4042 may be formed simultaneously, thereby simplifying the fabrication process.

In some examples, referring to FIG. 4A, the semiconductor device 400 may further comprise a connection structure 408. The connection structure 408 is located in the second region 400-2. The connection structure 408 extends along a third direction D3, the connection structure 408 extends through the isolation structure 404, and the third direction D3 is perpendicular to both the second direction D2 and the first direction D1.

As an example, the connection structure 408 shown in FIG. 4A extends through the second isolation portion 4044 along the third direction D3. Two opposite ends of the connection structure 408 along the third direction D3 may be connected to the conductive structure 406 and the interconnection structure 410 respectively, i.e., the conductive structure 406 and the interconnection structure 410 are connected through the connection structure 408. In this example, the connection structure 408 may further extend along the third direction D3 through the film layer between the conductive structure 406 and the first side S1 of the plurality of first semiconductor portions 402 and through the film layer between the interconnection structure 410 and the second side S2 of the plurality of first semiconductor portions 402. For ease of description, the film layer between the conductive structure 406 and the first side S1 of the plurality of first semiconductor portions 402 and the film layer between the interconnection structure 410 and the second side S2 of the plurality of first semiconductor portions 402 are omitted in FIG. 4A.

In other examples, the connection structure 408 may extend through the first isolation portion 4042 shown in FIG. 4B along the third direction D3, i.e., the connection structure 408 may extend through the second isolation portion 4044 or the first isolation portion 4042 along the third direction D3. A material of the connection structure 408 comprises a conductive material, for example, a metal material such as tungsten. It should be noted that in a case where the connection structure 408 extends through the isolation structure 404 located in the second region 400-2 along the third direction D3, the connection structure 408 and the first semiconductor portion 402 are physically isolated from each other.

In the examples of the present disclosure, by providing the connection structure 408 in the second region 400-2, the conductive structure and the interconnection structure may be connected with each other. In addition, since the at least one first semiconductor portion 402 extending in the second direction D2 is separated apart, the parasitic capacitance between the first semiconductor portion 402 and the connection structure 408 may also be reduced.

In some examples, referring to FIG. 4A, the semiconductor device 400 may further comprise an interconnection structure 410. The interconnection structure 410 is located on the second side S2 of the plurality of first semiconductor portions 402, wherein the second side S2 and the first side S1 are opposite along the third direction D3, and the connection structure 408 is connected to each of the conductive structure 406 and the interconnection structure 410.

As an example, FIG. 4A illustrates a plurality of interconnect structures 410. Each interconnect structure 410 of the plurality of interconnect structures 410 may be connected to the same conductive structure 406 through one connection structure 408. In other examples, each interconnection structure 410 may be connected to different conductive structures 406 through one connection structure 408, which is not specifically limited in the examples of the present disclosure.

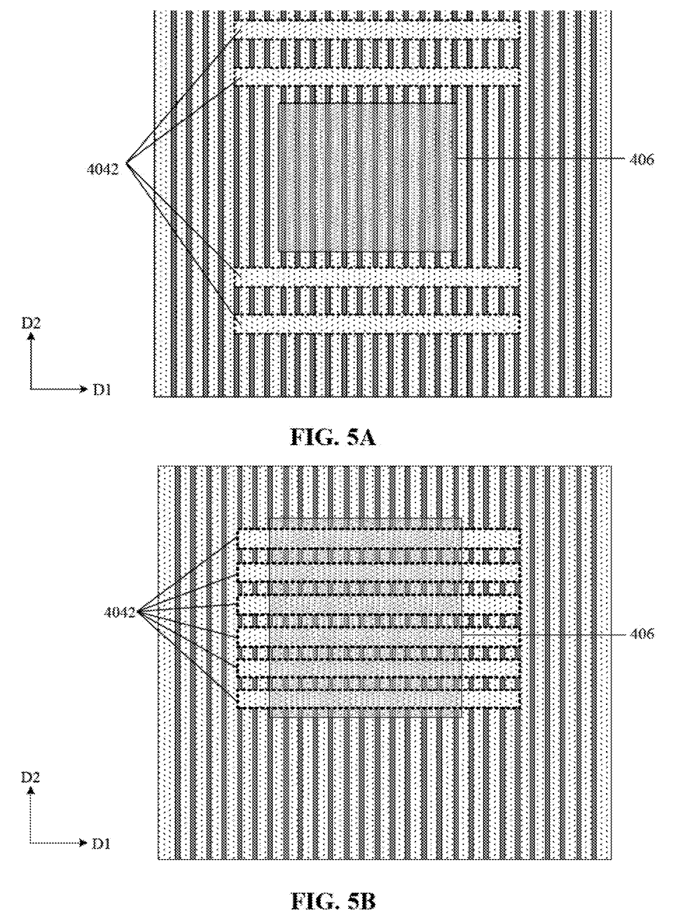

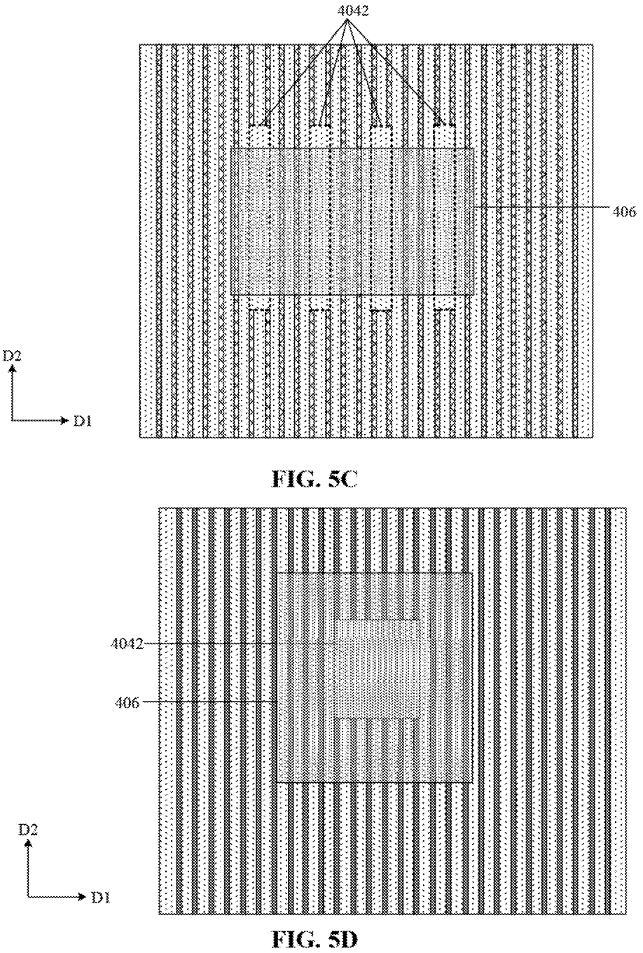

FIGS. 5A to 5D are top views of a first isolation portion according to an example of the present disclosure. It should be noted that in the examples shown in FIG. 5A to FIG. 5D, the same reference numeral is used for the same structure in FIG. 4A and FIG. 4B, and the same structure may refer to the related description of FIG. 4A and FIG. 4B, which will not be described in detail. This example only describes the different structures in detail.

Referring to FIGS. 4B, 5A and 5B, the isolation structure 404 comprises a plurality of first isolation portions 4042, and the plurality of first isolation portions 4042 are arranged along the second direction D2. In an example of the present disclosure, each first isolation portion 4042 may extend through one or more first semiconductor portions 402. The plurality of first isolation portions 4042 arranged along the second direction D2 may separate each first semiconductor portion 402 into a plurality of semiconductor sub-portions spaced apart from each other along the second direction D2, and each first isolation portion 4042 is located between two adjacent semiconductor sub-portions arranged along the second direction D2. As such, the plurality of first isolation portions 4042 may separate apart all of the plurality of first semiconductor portions 402 extending along the second direction D2 into the plurality of semiconductor sub-portions, which is conducive to further reducing the parasitic capacitance between the first semiconductor portion 402 and the conductive structure 406.

In some examples, N first isolation portions 4042 are arranged along the second direction D2, where N is a positive integer.

As an example, FIG. 4B shows two first isolation portions 4042 arranged along the second direction D2, FIG. 5A shows four first isolation portions 4042 arranged along the second direction D2, and FIG. 5B shows six first isolation portions 4042 arranged along the second direction D2. However, the number of the first isolation portions 4042 arranged along the second direction D2 is not limited to that shown in FIG. 4B, FIG. 5A and FIG. 5B, and may also be other numbers, which is not specifically limited in the examples of the present disclosure.

It may be understood that the N first isolation portions 4042 arranged in the second direction D2 may separate the first semiconductor portion 402 into (N+1) semiconductor sub-portions spaced apart from each other in the second direction D2, and sizes of any two semiconductor sub-portions in the second direction D2 may be the same or different.

In some other examples, referring to FIG. 5C, the first isolation portion 4042 extends in the second direction D2. In an example of the present disclosure, the first isolation portion 4042 extending along the second direction D2 may extend through one or more first semiconductor portions 402 and separate each first semiconductor portion 402 into two semiconductor sub-portions spaced apart from each other along the second direction D2. The first isolation portion 4042 is located between the two semiconductor sub-portions arranged along the second direction D2.

In some other examples, referring to FIG. 5C, the isolation structure 404 comprises a plurality of first isolation portions 4042, and the plurality of first isolation portions 4042 are arranged along the first direction D1. In an example of the present disclosure, each first isolation portion 4042 may extend through one or more first semiconductor portions 402. The plurality of first isolation portions 4042 arranged along the first direction D1 may separate each first semiconductor portion 402 into two semiconductor sub-portions spaced apart from each other along the second direction D2, and the first isolation portion 4042 is located between the two semiconductor sub-portions arranged along the second direction D2. As such, the plurality of first isolation portions 4042 may separate apart all of the plurality of first semiconductor portions 402 extending along the second direction D2 into the plurality of semiconductor sub-portions, which is conducive to further reducing the parasitic capacitance between the first semiconductor portion 402 and the conductive structure 406.

It should be noted that, in the plurality of first isolation portions 4042 arranged along the first direction D1 or the second direction D2 mentioned above, sizes of any two first isolation portions 4042 along the first direction D1 may be the same or different; and/or sizes of any two first isolation portions 4042 in the second direction D2 may be the same or different. The sizes of any two first isolation portions 4042 along the first direction D1 and/or the second direction D2 are not specifically limited in the examples of the present disclosure.

In some examples, the plurality of first isolation portions 4042 are arranged symmetrically on two opposite sides of the conductive structure 406 along the second direction D2. As an example, FIG. 4B shows that two first isolation portions 4042 are arranged symmetrically on two opposite sides of the conductive structure 406 along the second direction D2, and FIG. 5A shows that four first isolation portions 4042 are arranged symmetrically on two opposite sides of the conductive structure 406 along the second direction D2. However, the number of the first isolation portions 4042 arranged symmetrically on two opposite sides of the conductive structure 406 along the second direction D2 is not limited to that shown in FIG. 4B and FIG. 5A, and may also be other numbers, which is not specifically limited in the examples of the present disclosure.

In some examples, an orthographic projection of the conductive structure 406 and orthographic projections of the plurality of first isolation portions 4042 at least partially overlap. As an example, the orthographic projection of the conductive structure 406 shown in FIG. 5B and FIG. 5C and the orthographic projections of the plurality of first isolation portions 4042 partially overlap. As another example, the orthographic projection of the conductive structure 406 shown in FIG. 5D covers the orthographic projection of the first isolation portion 4042, i.e., the orthographic projection of the conductive structure 406 and the orthographic projection of the first isolation portion 4042 completely overlap.

In the examples of the present disclosure, the orthographic projection of the conductive structure 406 and the orthographic projections of the plurality of first isolation portions 4042 at least partially overlap, so that it can be ensured that the plurality of first semiconductor portions 402 right below the conductive structure 406 are all separated apart, which is conducive to further reducing the parasitic capacitance between the first semiconductor portion 402 and the conductive structure 406.

It should be noted that the technical solution of the first isolation portion provided by any example in FIG. 4B and FIG. 5A to FIG. 5D can reduce the parasitic capacitance between the first semiconductor portion and the conductive structure. For example, the parasitic capacitance between the semiconductor portion and the conductive structure in the second region shown in FIG. 3 is 101.2 femtofarads (fF), the parasitic capacitance between the first semiconductor portion and the conductive structure shown in FIG. 4B is 93.08 fF, and the parasitic capacitance between the first semiconductor portion and the conductive structure shown in FIG. 5D may be reduced to 93.01 fF.

However, in consideration of the backside flatness after subsequent thinning, it is provided with the technical solution of the first isolation portion in FIG. 4B in some examples. In an example, if a relatively large area of the first isolation portion shown in FIG. 5D is included in the second region, since a material of the first isolation portion is different from a material of the first semiconductor portion, a difference between thinning rates of the first isolation portion and the first semiconductor portion is relatively large during subsequent backside thinning, so that flatness of the thinned surface is relatively poor, which would affect subsequent processes. Therefore, the technical solution of the first isolation portion provided in FIG. 4B may not only reduce the parasitic capacitance but also ensure the flatness of the thinned surface.

In some examples, a size in the first direction D1 of the first isolation portion 4042 close to the conductive structure 406 is less than or equal to a size in the first direction D1 of the first isolation portion 4042 away from the conductive structure 406.

In an example of the present disclosure, etching starts from the second side S2 of the first semiconductor portion 402 to form a third trench extending along the first direction D1 or the second direction D2, and the third trench extends through the at least one first semiconductor portion 402 and is filled with an isolation material (for example, silicon oxide) to form the first isolation portion 4042. Due to the limitation of the deep hole etching process, the cross-sectional shape of the third trench may be trapezoidal or rectangular, such that the size in the first direction D1 of the first isolation portion 4042 close to the conductive structure 406 is less than or equal to the size in the first direction D1 of the first isolation portion 4042 away from the conductive structure 406.

In some other examples, a size in the first direction D1 of the first isolation portion 4042 close to the conductive structure 406 is greater than or equal to a size in the first direction D1 of the first isolation portion 4042 away from the conductive structure 406.

In an example of the present disclosure, etching starts from the first side S1 of the first semiconductor portion 402 to form a third trench extending along the first direction D1 or the second direction D2, and the third trench extends through the at least one first semiconductor portion 402 and is filled with an isolation material (e.g., silicon oxide) to form the first isolation portion 4042. Due to the limitation of the deep hole etching process, the cross-sectional shape of the third trench may be an inverted trapezoid or a rectangle, such that the size in the first direction D1 of the first isolation portion 4042 close to the conductive structure 406 is greater than or equal to the size in the first direction D1 of the first isolation portion 4042 away from the conductive structure 406.

In some other examples, the first isolation portion 4042 comprises a first isolation sub-portion and a second isolation sub-portion, and the second isolation sub-portion is located between the conductive structure 406 and the first isolation sub-portion; a size in the first direction D1 of the first isolation sub-portion close to the conductive structure 406 is greater than or equal to a size in the first direction D1 of the first isolation sub-portion away from the conductive structure 406; and a size in the first direction D1 of the second isolation sub-portion close to the conductive structure 406 is less than or equal to a size in the first direction D1 of the second isolation sub-portion away from the conductive structure 406.

In the examples of the present disclosure, the etching of the first semiconductor portion 402 may be divided into two operations to reduce the process difficulty of deep hole etching. For example, the etching may start from the first side S1 of the first semiconductor portion 402 to form a first sub-trench extending along the first direction D1 (or the second direction D2). The bottom of the first sub-trench extends into the etched first semiconductor portion 402. An isolation material (for example, silicon oxide) is filled into the first sub-trench to form a first isolation sub-portion; and then the etching starts from the second side S2 of the first semiconductor portion 402 to form a second sub-trench extending along the first direction D1 (or the second direction D2), the second sub-trench exposes the first isolation sub-portion, and an isolation material (for example, silicon oxide) is filled into the second sub-trench to form a second isolation sub-portion. As such, the size in the first direction D1 of the first isolation sub-portion close to the conductive structure 406 may be greater than or equal to the size in the first direction D1 of the first isolation sub-portion away from the conductive structure 406, and the size in the first direction D1 of the second isolation sub-portion close to the conductive structure 406 may be less than or equal to the size in the first direction D1 of the second isolation sub-portion away from the conductive structure 406.

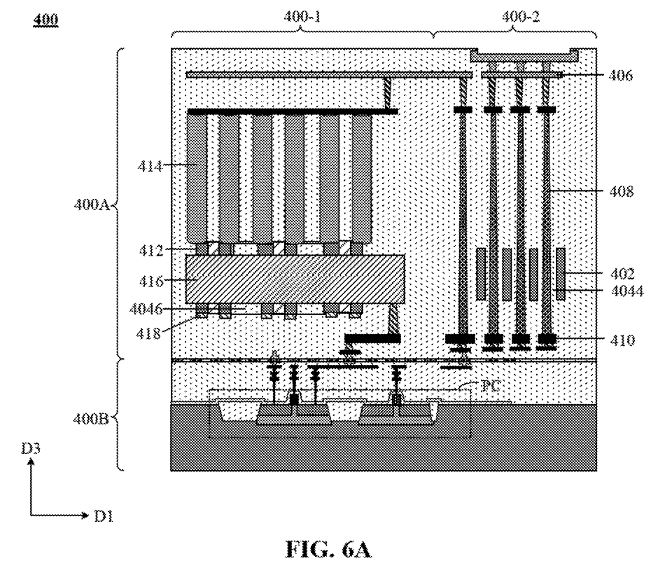

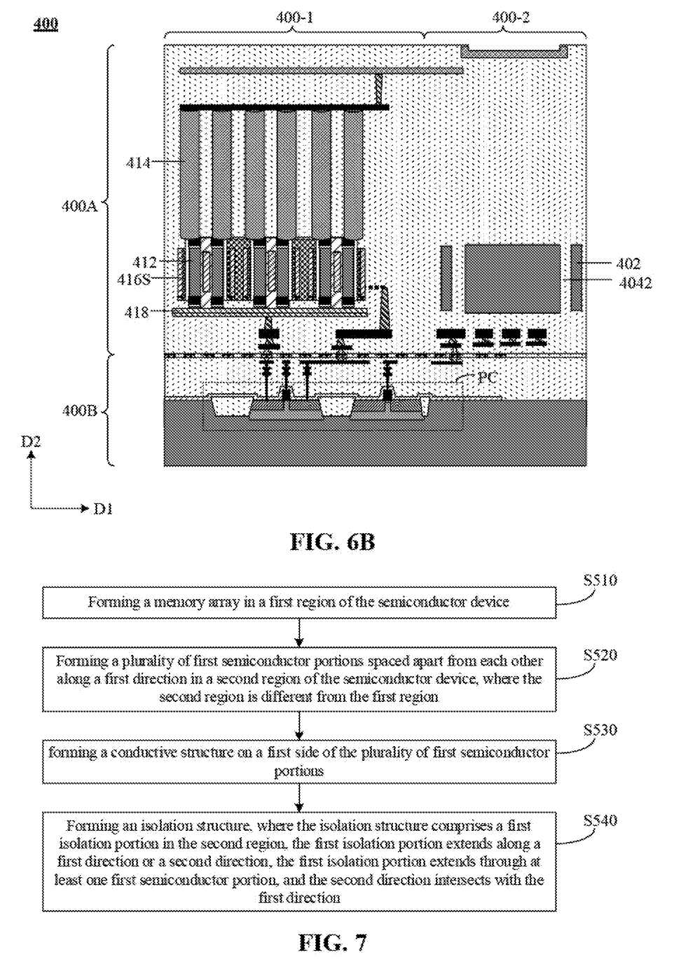

FIG. 6A is a schematic cross-sectional view of a semiconductor device along a first direction according to an example of the present disclosure, and FIG. 6B is a schematic cross-sectional view of a semiconductor device along a second direction according to an example of the present disclosure. It should be noted that in the examples shown in FIG. 6A and FIG. 6B, the same reference numeral is used for the same structure in FIG. 4A, FIG. 4B, and FIG. 5A to FIG. 5D, and the same structure may refer to the related description of FIG. 4A, FIG. 4B, and FIG. 5A to FIG. 5D, which will not be described in detail. This example only describes different structures in detail.

Referring to FIGS. 6A and 6B, the semiconductor device 400 comprises a first semiconductor structure 400A and a second semiconductor structure 400B bonded together, where the memory array, the conductive structure 406, the isolation structure and the plurality of first semiconductor portions 402 are in the first semiconductor structure 400A, and the connection structure 408 extends through a portion of the first semiconductor structure 400A along the third direction D3.

In the examples of the present disclosure, the memory array, the conductive structure 406, the isolation structure 404 and the plurality of first semiconductor portions 402 are arranged in the first semiconductor structure 400A, and the memory array and the conductive structure 406 are connected through the connection structure 408. As such, the integration of the semiconductor device 400 is improved, and the size of the semiconductor device 400 is scaled down.

It should be noted that the bonding connection mentioned above includes a hybrid bonding connection (also referred to as a “metal/dielectric hybrid bonding connection”), which is a direct bonding technology, for example, bonding between surfaces is formed without an intermediate layer such as a solder or an adhesive, and both metal-metal bonding and dielectric-dielectric bonding can be obtained. It should be noted that the “bonding” referred to in the present disclosure may be any suitable bonding technology, such as hybrid bonding, anodic bonding, fusion bonding, transfer bonding, adhesive bonding, eutectic bonding, and the like mentioned above.

In some examples, referring to FIGS. 6A and 6B, the memory array comprises a plurality of second semiconductor portions 412. The plurality of second semiconductor portions 412 are located in the first region 400-1 and arranged in an array along the first direction D1 and the second direction D2. In an example of the present disclosure, the second semiconductor portion 412 may constitute a transistor of the DRAM memory cell. The plurality of second semiconductor portions 412 may constitute a plurality of transistors respectively, and the plurality of transistors are connected to the plurality of capacitors 414 respectively, thereby constituting a plurality of DRAM memory cells arranged in an array, i.e., a memory array. The plurality of second semiconductor portions 412 arranged in an array may be formed by etching the substrate located in the first region 400-1.

In some examples, the material of the second semiconductor portion 412 is the same as the material of the first semiconductor portion 402. In an example of the present disclosure, the substrate located in the first region 400-1 and the second region 400-2 may be etched simultaneously to form a plurality of first semiconductor portions 402 and a plurality of second semiconductor portions 412 in the first region 400-1 and the second region 400-2 respectively, so that the material of the first semiconductor portion 402 and the material of the second semiconductor portion 412 are the same as the material of the substrate. Regarding to the material of the second semiconductor portion 412, reference may be made to the related description of the material of the first semiconductor portion 402, which will not be repeated here. Since the etching of the plurality of second semiconductor portions 412 and the etching of the plurality of first semiconductor portions 402 may be performed simultaneously, the fabrication process may be simplified.

It should be noted that the second semiconductor portion 412 may serve as a dummy structure that may protect the memory array. Specifically, the second semiconductor portion 412 is generally not electrically connected to other structures in the semiconductor device, and can be removed in theory, so that the parasitic capacitance is smaller. However, in the actual fabrication process, if the silicon in the second region is directly removed, and if the isolation material (for example, silicon oxide) is filled at the position where the silicon is removed, the grinding rate of the second region is faster than the grinding rate of the first region when the substrate is thinned from the backside, so that the second region has recesses, which would affect the subsequent process. Therefore, the second region is provided with silicon as the same as the first region, i.e., the second semiconductor portion 412 is provided and it may have a function of supporting and reduce the polishing rate difference in different regions.

In some examples, the height of the second semiconductor portion 412 is substantially the same as the height of the first semiconductor portion 402. As an example, the surface of the second semiconductor portion 412 close to the conductive structure 406 and the surface of the first semiconductor portion 402 close to the conductive structure 406 are at substantially the same height, i.e., the surface of the second semiconductor portion 412 close to the conductive structure 406 and the surface of the first semiconductor portion 402 close to the conductive structure 406 are substantially coplanar. The surface of the second semiconductor portion 412 away from the conductive structure 406 and the surface of the first semiconductor portion 402 away from the conductive structure 406 are at substantially the same height, i.e., the surface of the second semiconductor portion 412 away from the conductive structure 406 and the surface of the first semiconductor portion 402 away from the conductive structure 406 are substantially coplanar.

In some examples, referring to FIG. 6A, the isolation structure 404 further comprises a third isolation portion 4046. The third isolation portion 4046 is located between adjacent second semiconductor portions 412 along the first direction D1, where a height of the third isolation portion 4046 is substantially the same as a height of the first isolation portion 4042. The third isolation portion 4046 may physically isolate the plurality of second semiconductor portions 412 spaced apart from each other along the first direction D1 from each other, and a material of the third isolation portion 4046 comprises at least one of silicon oxide, silicon nitride, and silicon oxynitride.

In some examples, the first isolation portion 4042, the second isolation portion 4044, and the third isolation portion 4046 have the same material, for example, the first isolation portion 4042, the second isolation portion 4044, and the third isolation portion 4046 may all be silicon oxide.

In some examples, referring to FIG. 6A and FIG. 6B, the memory array further comprises a transistor and a capacitor 414; the transistor comprises a second semiconductor portion 412; the capacitor 414 is located on a side of the second semiconductor portion 412 close to the conductive structure 406, and the capacitor 414 is connected to an end of the second semiconductor portion 412 close to the conductive structure 406.

The transistor may comprise a second semiconductor portion 412 and a gate structure. The second semiconductor portion 412 comprises a source, a channel, and a drain arranged sequentially in the third direction D3. The gate structure comprises a gate 416S and a gate dielectric layer. The gate 416S covers at least one sidewall of the channel, and the gate dielectric layer is located between the gate 416S and the channel. The capacitor 414 may comprise a first electrode plate, a second electrode plate, and a capacitive medium between the first electrode plate and the second electrode plate.

As an example, referring to FIGS. 6A and 6B, the gates 416S of the plurality of transistors arranged along the first direction D1 are connected to the same word line 416. Referring to FIG. 6B, the drains of the plurality of transistors arranged along the second direction D2 are connected to the same bit line 418, the first electrode plate is connected to the source of the transistor, and the second electrode plate is connected to the common terminal. In this example, the source of the transistor may be an end of the second semiconductor portion 412 close to the conductive structure 406, and the drain of the transistor may be an end of the second semiconductor portion 412 away from the conductive structure 406.

In other examples, the positions of the drain and the source of the transistor may be interchanged. For example, the gates 416S of the plurality of transistors arranged along the first direction D1 are connected to the same word line 416, the sources of the plurality of transistors arranged along the second direction D2 are connected to the same bit line 418, the first electrode plate is connected to the drain of the transistor, and the second electrode plate is connected to the common terminal.

In some examples, referring to FIGS. 6A and 6B, the second semiconductor structure 400B further comprises a peripheral circuit (PC), which may be connected to the interconnection structure 410 through bonding contacts. As an example, referring to FIG. 6A, the memory array may be connected to the peripheral circuit (PC) through the conductive structure 406, the connection structure 408, the interconnection structure 410 and the bonding contacts.

It should be noted that the bonding contacts may be located at the bonding interface of the first semiconductor structure 400A and the second semiconductor structure 400B.

Based on the above semiconductor device, an example of the present disclosure provides a fabrication method of a semiconductor device, which may be implemented to form the semiconductor device in any of the above examples.

FIG. 7 is a flow diagram of a fabrication method of a semiconductor device according to an example of the present disclosure. It should be noted that the operations as shown in FIG. 7 are not exclusive, and other operations may be performed before, after, or between any of the operations as shown; and the sequence of the operations as shown in FIG. 7 may be adjusted according to actual requirements. Referring to FIG. 7, the fabrication method comprises at least the following operations:

S510: forming a memory array in a first region of the semiconductor device;

S520: forming a plurality of first semiconductor portions spaced apart from each other along a first direction in a second region of the semiconductor device, where the second region is different from the first region;

S530: forming a conductive structure on a first side of the plurality of first semiconductor portions;

S540: forming an isolation structure, where the isolation structure comprises a first isolation portion in the second region, the first isolation portion extends along a first direction or a second direction, the first isolation portion extends through at least one first semiconductor portion, and the second direction intersects with the first direction.

In the examples of the present disclosure, the isolation structure comprises the first isolation portion located in the second region, and the first isolation portion extends through the at least one first semiconductor portion. Due to the formation of the isolation structure, the plurality of first semiconductor portions extending in the second direction can be separated apart, thereby reducing the parasitic capacitance between the first semiconductor portion and the conductive structure, and improving the speed of inputting or outputting data by the semiconductor device.

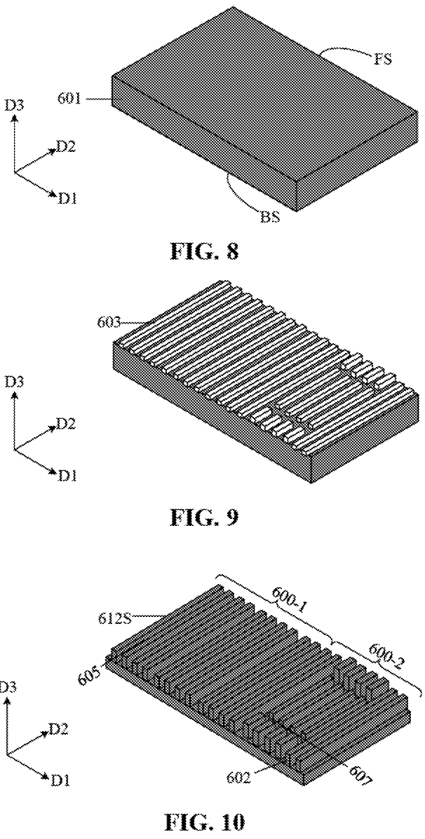

FIG. 8 to FIG. 11 are partial schematic diagrams illustrating a fabrication process of a semiconductor device according to an example of the present disclosure. The fabrication method of the semiconductor device provided by the examples of the present disclosure will be illustrated below with reference to FIGS. 7 and 8 to 11.

In S510, a memory array is formed in a first region of a semiconductor device. As an example, a plurality of transistors and a plurality of capacitors may be formed in the first region of the semiconductor device. One transistor and one capacitor are connected to form a memory cell, and a plurality of memory cells may form a memory array.

In some examples, the above S510 comprises: forming a plurality of second semiconductor portions arranged in an array along the first direction and the second direction in the first region. As an example, a plurality of second semiconductor portions arranged in an array may be formed by etching the substrate in the first region, the second semiconductor portions may constitute transistors of the DRAM memory cell, and the plurality of second semiconductor portions may constitute a plurality of transistors respectively.

In S520, a plurality of first semiconductor portions spaced apart from each other along the first direction are formed in a second region of the semiconductor device, where the second region is different from the first region. As an example, a plurality of first semiconductor portions spaced apart from each other along the first direction may be formed by etching the substrate in the second region, and the first semiconductor portions in the second region may serve as dummy structures.

In S530, a conductive structure is formed on a first side of the plurality of first semiconductor portions. The conductive structure may be electrically coupled to the memory array, the conductive structure may input data to be written to the memory array, or the conductive structure may output data read from the memory array.

In S540, an isolation structure is formed. The isolation structure comprises a first isolation portion in the second region, where the first isolation portion extends along a first direction or a second direction, the first isolation portion extends through at least one first semiconductor portion, and the second direction intersects with the first direction. The first isolation portion is located in the second region, and the first isolation portion may separate apart at least one first semiconductor portion extending in the second direction, thereby reducing the parasitic capacitance between the first semiconductor portion and the conductive structure.

In some examples, the above S540 comprises: forming a second isolation portion between adjacent first semiconductor portions along the first direction, where a height of the second isolation portion is substantially the same as a height of the first isolation portion. The second isolation portion is located in the second region, and the second isolation portion may physically isolate the plurality of first semiconductor portions spaced apart from each other along the first direction from each other.

In some examples, the above S540 comprises: forming a third isolation portion between adjacent second semiconductor portions along the first direction, where a height of the third isolation portion is substantially the same as a height of the first isolation portion. The third isolation portion is located in the first region, and the third isolation portion may physically isolate the plurality of second semiconductor portions spaced apart from each other along the first direction from each other.

In some examples, the above S540 comprises: providing a substrate; etching the substrate to form a plurality of first trenches spaced apart from each other along a first direction, where the first trenches in the second region separate the substrate into a plurality of first semiconductor portions, and the first trenches in the first region separate the substrate into a plurality of initial second semiconductor portions; and forming initial isolation portions in the plurality of first trenches, where the initial isolation portions in the second region constitute the second isolation portions.

Referring to FIG. 8, a substrate 601 is provided. The substrate 601 serves as a growth and supporting substrate in a subsequent material layer deposition process. The substrate 601 may be a semiconductor substrate. The substrate 601 may comprise a front surface FS and a back surface BS opposite to each other in the third direction D3.

Referring to FIG. 8 and FIG. 9, a patterned mask layer 603 may be formed on the FS of the substrate 601, and the substrate 601 is etched based on the patterned mask layer 603 to form a plurality of first trenches 605 as shown in FIG. 10. The plurality of first trenches 605 are spaced apart from each other along the first direction D1. Each first trench 605 extends along the second direction D2, and the bottom of the first trench 605 extends to between the front surface and the back surface of the substrate 601. Here, the first trench 605 in the second region 600-2 may separate the substrate 601 into a plurality of first semiconductor portions 602 spaced apart from each other along the first direction D1, and the first trench 605 in the first region 600-1 may separate the substrate 601 into a plurality of initial second semiconductor portions 612S spaced apart from each other along the first direction D1.

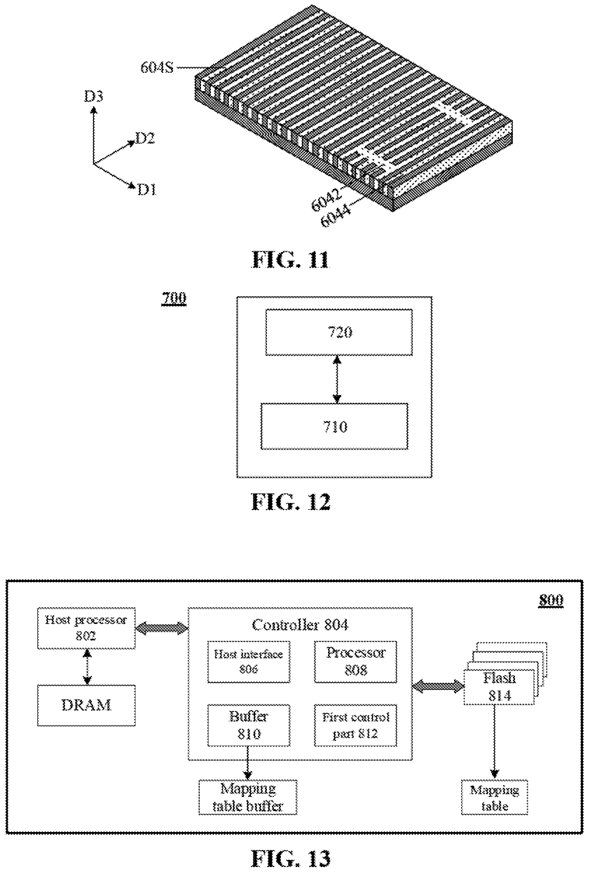

The first trench 605 shown in FIG. 10 is filled with an isolation material, and an initial isolation portion 604S shown in FIG. 11 may be formed in each first trench 605. A plurality of initial second semiconductor portions 612S and a plurality of initial isolation portions 604S may be arranged alternately along the first direction D1 in the first region 600-1. A plurality of first semiconductor portions 602 and a plurality of initial isolation portions 604S may be arranged alternately along the first direction D1 in the second region 600-2. Here, the initial isolation portion 604S located in the second region 600-2 constitutes the second isolation portion 6044.

In some examples, the above S540 further comprises: etching the at least one first semiconductor portion to form a third trench extending along the first direction or the second direction, the third trench extending through the at least one first semiconductor portion; and forming the first isolation portion in the third trench.

As an example, the plurality of first semiconductor portions 602 are etched to form the third trench 607 as shown in FIG. 10. The third trench 607 extends along the first direction D1, and the bottom of the third trench 607 may be flush with the bottom of the first trench 605, so that the plurality of first semiconductor portions 602 are separated apart, i.e., the third trench 607 extends through the plurality of first semiconductor portions 602. The third trench 607 as shown in FIG. 10 is filled with an isolation material, and the first isolation portion 6042 as shown in FIG. 11 may be formed in the third trench 607. In other examples, the third trench 607 may extend through one first semiconductor portion 602, i.e., the third trench 607 separate apart one first semiconductor portion 602 extending in the second direction D2.

In some examples, the third trench and the plurality of first trenches are formed simultaneously by etching, and the first isolation portion and the initial isolation portion are formed simultaneously.

As an example, the substrate 601 may be etched based on the patterned mask layer 603 shown in FIG. 9 to form the third trench 607 and the first trench 605 shown in FIG. 10 simultaneously. Two opposite ends of the first trench 605 along the first direction D1 may be connected with two third trenches 607. The third trench 607 and the first trench 605 may be filled with an isolation material simultaneously, to form the first isolation portion 6042 and the initial isolation portion 604S shown in FIG. 11 simultaneously. As such, the third trench 607 and the first trench 605 may be etched by using the same mask, and the third trench 607 and the first trench 605 are filled simultaneously, which is conducive to simplifying processes and reducing fabrication costs.

In some examples, forming a plurality of second semiconductor portions arranged in an array along the first direction and the second direction in the first region comprises: etching a plurality of initial second semiconductor portions and an initial isolation portion located in the first region to form a plurality of second trenches spaced apart from each other along the second direction, where the plurality of second trenches separate the initial second semiconductor portions into a plurality of second semiconductor portions. The initial isolation portions on both sides of the second trenches constitute a third isolation portion.

As an example, the plurality of initial second semiconductor portions 612S shown in FIG. 11 and the initial isolation portions 604S located in the first region 600-1 may continue to be etched to form a plurality of second trenches spaced apart from each other along the second direction D2. Each second trench extends along the first direction D1 in the first region 600-1, thereby forming a plurality of second semiconductor portions arranged in an array along the first direction D1 and the second direction D2. The initial isolation portions 604S remained in the first region 600-1 constitute the third isolation portions.

In some examples, the above fabrication method further comprises: forming a gate structure and a word line in the second trench. Specifically, a gate dielectric layer, a gate, and a word line may be formed in the second trench. The gate dielectric layer and the gate constitute a gate structure. The word line extends along the first direction D1, and the same word line is connected to gates of a plurality of transistors arranged along the first direction D1. Regarding to the gate and the word line, reference may be made to related description of the gate 416S and the word line 416 shown in FIG. 6A and FIG. 6B.

In some examples, the above S510 comprises: forming a capacitor on the second semiconductor portion. For example, a capacitor 414 as shown in FIG. 6A and FIG. 6B may be formed on the front surface of each second semiconductor portion. The first electrode plate of the capacitor 414 is connected to the second semiconductor portion (for example, the source of the transistor) exposed on the front surface. It may be understood that the front surface of the substrate is the front surface of the second semiconductor portion.

In some examples, the plurality of first trenches are formed on a front surface of the substrate, and the third trench is formed on a back surface of the thinned substrate, where a distance between the front surface of the substrate and the conductive structure is less than a distance between the back surface of the substrate and the conductive structure.

In the examples of the present disclosure, the plurality of first trenches 605 shown in FIG. 10 may be formed by etching from the FS of the substrate 601. After structures such as a memory array are formed, the substrate 601 is thinned from the BS of the substrate 601 until the first semiconductor portion 602 is exposed. The exposed first semiconductor portion 602 is etched to form the third trench 607, i.e., the third trench 607 is formed on the BS of the thinned substrate 601. It can be understood that the FS of the substrate 601 corresponds to the first side of the first semiconductor portion 602, and the BS of the thinned substrate 601 corresponds to the second side of the first semiconductor portion 602. Since the conductive structure is located on the first side of the first semiconductor portion 602, a distance between the FS of the substrate 601 and the conductive structure is less than a distance between the BS of the substrate 601 and the conductive structure.

In some examples, the above S540 further comprises: etching at least one first semiconductor portion to form a first sub-trench, where a bottom of the first sub-trench extends into the etched first semiconductor portion; forming a first isolation sub-portion in the first sub-trench, where a size of the first isolation sub-portion close to the conductive structure along the first direction is greater than or equal to a size of the first isolation sub-portion away from the conductive structure along the first direction; after thinning the substrate, etching the remaining first semiconductor portion to form a second sub-trench, where the second sub-trench exposes the first isolation sub-portion; and forming a second isolation sub-portion in the second sub-trench, where a size of the second isolation sub-portion close to the conductive structure along the first direction is less than or equal to a size of the second isolation sub-portion away from the conductive structure along the first direction.

In some examples, the etching of the first semiconductor portion 602 may be divided into two operations. For example, the etching starts from the FS of the substrate 601 to form a first sub-trench. The bottom of the first sub-trench extends into the etched first semiconductor portion 602. An isolation material (for example, silicon oxide) is filled into the first sub-trench to form a first isolation sub-portion; and then the etching starts from the thinned BS of the substrate 601 to form a second sub-trench, the second sub-trench exposes the first isolation sub-portion, and an isolation material (for example, silicon oxide) is filled into the second sub-trench to form a second isolation sub-portion.

In some examples, the above fabrication method further comprises: forming a connection structure in the second region, where the connection structure extends along a third direction, the connection structure extends through the isolation structure, and the third direction is perpendicular to both the second direction and the first direction.

In the examples of the present disclosure, the substrate 601 may also be thinned until the second semiconductor portion is exposed, the exposed second semiconductor portion is doped to form the drain of the transistor, and the bit line connected to the drain of the transistor is formed. After the bit line is formed, etching starts from the BS of the thinned substrate 601, and a connection hole extending through the second isolation portion 6044 is formed in the second region 600-2. The connection hole exposes the interconnection line formed on the FS of the substrate 601. The connection hole is filled with a conductive material to form a connection structure connected to the interconnection line.

In some examples, the above fabrication method further comprises: forming an interconnection structure on a second side of the plurality of first semiconductor portions, where the second side and the first side are opposite along the third direction, and the connection structure is connected to each of the conductive structure and the interconnection structure.

In an example of the present disclosure, the interconnection structure 410 as shown in FIG. 6A may be formed on BS of the substrate 601. The interconnection structure 410 may be located in the second region 600-2 and may be connected to the conductive structure 406 through the connection structure 408.

In some examples, the above fabrication method further comprises: bonding the first semiconductor structure to the second semiconductor structure, the first semiconductor structure comprising the memory array, the conductive structure, the isolation structure and the plurality of first semiconductor portions, where the connection structure extends through a portion of the first semiconductor structure along the third direction.

In the examples of the present disclosure, a first semiconductor structure may be formed based on the substrate 601. The first semiconductor structure comprises a memory array, a conductive structure, an isolation structure, a plurality of first semiconductor portions 602, and the like; a second semiconductor structure may be formed based on another substrate, and the second semiconductor structure comprises a peripheral circuit, and the like; and the first semiconductor structure and the second semiconductor structure are bonded, and the interconnection structure may be connected to the peripheral circuit through bonding contacts of the bonding interface. The conductive structure may comprise a data pad.

In the examples of the present disclosure, the fabrication method of the semiconductor device may be implemented to form the semiconductor device in any of the foregoing examples, and the technical effects that can be achieved by the semiconductor device in the foregoing examples can also be achieved, which will not be repeated here.

Based on the above semiconductor device, an example of the present disclosure provides a memory system.

FIG. 12 is a schematic diagram of a memory system according to an example of the present disclosure. Referring to FIG. 12, the memory system 700 comprises at least one semiconductor device 710, and there may be one or more semiconductor devices 710. Regarding to the memory system 700, reference may be made to the related description of the memory system 30 in FIG. 1, and regarding to the semiconductor device 710, reference may be made to the related description of the semiconductor device 400 in FIGS. 4A, 4B, 5A-5D, 6A and 6B.

The memory system 700 further comprises a controller 720 coupled to the semiconductor device 710. Regarding to the controller 720, reference may be made to related description of the controller 10 in FIG. 1.

In some examples, memory system 700 comprises a high bandwidth memory.

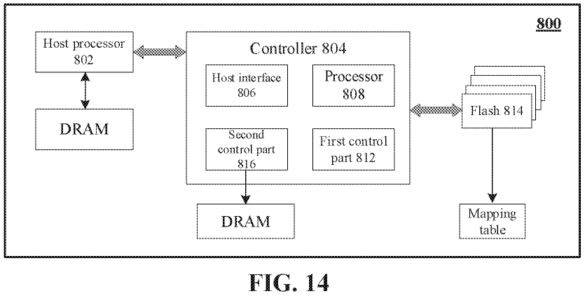

In some other examples, the semiconductor device 710 may be a DRAM, and the DRAM may be disposed outside the memory system and coupled to the host processor. In other examples, the DRAM may also be a part of the controller in the memory system and connected to the corresponding control part. The following provides example illustrations with reference to FIG. 13 and FIG. 14.

FIG. 13 is a schematic diagram illustrating another system according to an example of the present disclosure. System 800 may comprise a host and a memory system coupled to the host. In this example, the DRAM may be disposed outside the memory system and coupled to the host processor 802.

Referring to FIG. 13, the host may comprise a host processor 802 and a DRAM coupled to the host processor 802. The host processor 802 may serve as a central processing unit of the system 800 and is configured for executing various computing tasks and control instructions and performing data exchange and communication with other modules in the system 800. The DRAM coupled to the host processor 802 may provide a high-speed temporary data storage space, support fast read and write operations of the host processor 802, and improve the overall performance of the system 800.

Referring to FIG. 13, the memory system may comprise a controller 804 and a flash memory 814 coupled to the controller 804. The controller 804 may comprise a host interface 806, a processor 808, a buffer 810, and a first control part 812. The host interface 806 may provide a data transmission interface, support a connection to the host processor 802 or another external device, and enable data transmission. Host interface 806 comprises a PCIe interface, SATA interface, or other interface. The processor 808 is a central processing unit built in the controller 804 and is configured for processing data management and control tasks inside the memory system to improve data processing efficiency. The buffer 810 may buffer temporary data and control information inside the memory system to support quick access of data. The buffer 810 comprises SRAM, and the controller 804 may buffer the mapping table stored in the flash memory 814 into SRAM when the memory system is powered on. The first control part 812 is configured for managing various operations of the flash memory 814, including mapping, erasing, reading, writing and the like of data, and ensuring the reliability and performance of the data.

FIG. 14 is a schematic diagram illustrating yet another system according to an example of the present disclosure. In this example, the DRAM may also be a part of the controller 804 in the memory system and is connected to a corresponding control part. Referring to FIG. 14, the DRAM belonging to the controller 804 in the memory system is coupled to the second control part 816. Here, the DRAM may be externally mounted and form a part of the controller 804, and the externally mounted DRAM may serve as a buffer of the controller 804. In another example, the DRAM may also be integrated into the controller 804.

In the examples of the present disclosure, the semiconductor device 710 may be the same as the semiconductor device 400 in any of the foregoing examples, and the semiconductor device 710 can also achieve the technical effects that can be achieved by the semiconductor device 400 in the foregoing examples, which will not be repeated here.

The features disclosed in several apparatus examples provided by the present disclosure may be arbitrarily combined without conflict to obtain new apparatus examples.

The methods disclosed in the several method examples provided in the present disclosure may be arbitrarily combined without conflict to obtain new method examples.

It should be understood that “one example” or “an example” throughout the specification means that particular features, structures, or characteristics related to the example are included in at least one example of the present disclosure. Therefore, “in one example” or “in an example” throughout the specification does not necessarily refer to the same example. Furthermore, the particular features, structures, or characteristics may be combined in any suitable manner in one or more examples. It should be understood that, in various examples of the present disclosure, the sequence numbers of the above processes do not indicate an execution sequence, and the execution sequence of each process should be determined by its function and internal logic, and should not constitute any limitation on the implementation process of the examples of the present disclosure. The sequence numbers of the above examples of the present disclosure are only for description, and do not represent the advantages or disadvantages of the examples.

It should be noted that, the terms “including”, “comprising”, or any other variation thereof herein are intended to encompass a non-exclusive inclusion, so that a process, a method, an article, or an apparatus that includes a series of elements includes not only those elements, but also other elements that are not explicitly listed, or elements inherent to such a process, method, article, or apparatus. Without more constraints, an element defined by the phrase “comprising one” does not preclude the existence of additional identical elements in the process, method, article, or apparatus that comprises the element.

The above descriptions are only some implementations of the present disclosure, and the scope of protection of the present disclosure is not limited thereto. Any variant or replacement that may be readily conceived by those skilled in the art within the scope of the present disclosure should be encompassed within the scope of protection of the present disclosure.

What is claimed is:

1. A semiconductor device, comprising:
a memory array in a first region of the semiconductor device;
first semiconductor portions in a second region of the semiconductor device, the first semiconductor portions being spaced apart from each other along a first direction, wherein the second region is different from the first region;
a conductive structure on a first side of the first semiconductor portions; and
an isolation structure comprising a first isolation portion in the second region,
wherein the first isolation portion extends along the first direction or a second direction, the first isolation portion extends through at least one of the first semiconductor portions, and the second direction intersects with the first direction.

2. The semiconductor device of claim 1, wherein
the isolation structure further comprises a second isolation portion between adjacent first semiconductor portions along the first direction; and
a height of the second isolation portion is substantially the same as a height of the first isolation portion.

3. The semiconductor device of claim 1, wherein
the memory array comprises second semiconductor portions located in the first region and arranged in an array along the first direction and the second direction; and
the isolation structure further comprises a third isolation portion between adjacent second semiconductor portions along the first direction, a height of the third isolation portion being substantially the same as a height of the first isolation portion.

4. The semiconductor device of claim 3, wherein a size in the first direction of the first isolation portion close to the conductive structure is greater than or equal to a size in the first direction of the first isolation portion away from the conductive structure.

5. The semiconductor device of claim 3, wherein a height of the second semiconductor portion is substantially the same as a height of the first semiconductor portion, and a material of the second semiconductor portion is the same as a material of the first semiconductor portion.

6. The semiconductor device of claim 1, wherein a size in the first direction of the first isolation portion close to the conductive structure is less than or equal to a size in the first direction of the first isolation portion away from the conductive structure.

7. The semiconductor device of claim 1, wherein the first isolation portion comprises:
a first isolation sub-portion, wherein a size in the first direction of the first isolation sub-portion close to the conductive structure is greater than or equal to a size in the first direction of the first isolation sub-portion away from the conductive structure; and
a second isolation sub-portion between the conductive structure and the first isolation sub-portion, a size in the first direction of the second isolation sub-portion close to the conductive structure being less than or equal to a size in the first direction of the second isolation sub-portion away from the conductive structure.

8. The semiconductor device of claim 1, wherein the first isolation portion extends through the first semiconductor portions.

9. The semiconductor device of claim 1, wherein an orthographic projection of the conductive structure and orthographic projections of the first isolation portion at least partially overlap, and the conductive structure comprises a data pad.

10. The semiconductor device of claim 1, wherein the memory array further comprises:
a transistor comprising a second semiconductor portion; and
a capacitor on a side of the second semiconductor portion close to the conductive structure, the capacitor being connected to an end of the second semiconductor portion close to the conductive structure.

11. The semiconductor device of claim 1, further comprising:
a connection structure in the second region,
wherein the connection structure extends along a third direction, the connection structure extends through the isolation structure, and the third direction is perpendicular to both the second direction and the first direction.

12. The semiconductor device of claim 11, wherein
the semiconductor device comprises a first semiconductor structure and a second semiconductor structure that are bonded together; and
the memory array, the conductive structure, the isolation structure, and the first semiconductor portions are located in the first semiconductor structure, and the connection structure extends through a portion of the first semiconductor structure along the third direction.

13. The semiconductor device of claim 11, wherein
the semiconductor device further comprises an interconnection structure on a second side of the first semiconductor portions;
the second side and the first side are opposite along the third direction; and
the connection structure is connected to each of the conductive structure and the interconnection structure.

14. The semiconductor device of claim 1, wherein the semiconductor device comprises a dynamic random access memory.

15. A fabrication method of a semiconductor device, comprising:
forming a memory array in a first region of the semiconductor device;
forming a first semiconductor portions spaced apart from each other along a first direction in a second region of the semiconductor device, wherein the second region is different from the first region;
forming a conductive structure on a first side of the first semiconductor portions; and
forming an isolation structure comprising a first isolation portion in the second region, wherein the first isolation portion extends along the first direction or a second direction, the first isolation portion extends through at least one of the first semiconductor portions, and the second direction intersects with the first direction.

16. The fabrication method of claim 15, wherein forming the isolation structure comprises:
forming a second isolation portion between adjacent first semiconductor portions along the first direction, a height of the second isolation portion being substantially the same as a height of the first isolation portion.

17. The fabrication method of claim 15, wherein
forming the memory array in the first region of the semiconductor device comprises forming a second semiconductor portion arranged in an array along the first direction and the second direction in the first region; and
forming the isolation structure comprises forming a third isolation portion between adjacent second semiconductor portions along the first direction; and
a height of the third isolation portion is substantially the same as a height of the first isolation portion.

18. The fabrication method of claim 17, wherein
forming the isolation structure comprises:
providing a substrate;
etching the substrate to form a first trenches spaced apart from each other along the first direction, wherein the first trenches in the second region separate the substrate into the first semiconductor portions, and the first trenches in the first region separate the substrate into an initial second semiconductor portions;
forming an initial isolation portion in the first trenches, wherein the initial isolation portion in the second region constitutes the second isolation portion; and
forming the second semiconductor portions arranged in an array along the first direction and the second direction in the first region comprises:
etching the initial second semiconductor portions and the initial isolation portion in the first region to form a second trenches spaced apart from each other along the second direction, wherein the second trenches separate the initial second semiconductor portions into the second semiconductor portions, and the initial isolation portion on both sides of the second trenches constitutes the third isolation portion.

19. The fabrication method of claim 18,
wherein forming the isolation structure further comprises:
etching at least one of the first semiconductor portions to form a third trench extending along the first direction or the second direction, the third trench extending through the at least one of the first semiconductor portions; and
forming the first isolation portion in the third trench; and
wherein the third trench and the first trenches are formed simultaneously by etching, and the first isolation portion and the initial isolation portion are formed simultaneously.

20. A memory system, comprising:
at least one semiconductor device, comprising:
a memory array in a first region of the semiconductor device;
a first semiconductor portion in a second region of the semiconductor device, the first semiconductor portion being spaced apart from each other along a first direction, wherein the second region is different from the first region;
a conductive structure on a first side of the first semiconductor portions; and
an isolation structure comprising a first isolation portion in the second region,
wherein the first isolation portion extends along the first direction or a second direction, the first isolation portion extends through at least one of the first semiconductor portions, and the second direction intersects with the first direction; and
a controller coupled to the semiconductor device.
